(19) United States
(12) Patent Application Publication
(10) Pub. No.: US 2026/0173742 A1
(43) Pub. Date: Jun. 18, 2026

(54) DISPLAY PANEL AND METHOD OF MANUFACTURING THE SAME

(71) Applicants: Hefei Visionox Technology Co., Ltd., Hefei (CN); Visionox Technology Inc., Kunshan (CN)

(72) Inventors: Zhiwei ZHOU, Hefei (CN); Jinfang ZHANG, Hefei (CN); Aihua XUE, Kunshan (CN); Peng QIN, Hefei (CN)

(73) Assignees: Hefei Visionox Technology Co., Ltd., Hefei (CN); Visionox Technology Inc., Kunshan (CN)

(21) Appl. No.: 19/305,702

(22) Filed: Aug. 20, 2025

(30) Foreign Application Priority Data
Dec. 13, 2024 (CN) 202411847045.2

(51) Int. Cl. H10K 59/80; H10K 59/12; H10K 59/122

(52) U.S. Cl. CPC H10K 59/8792; H10K 59/1201; H10K 59/122

(57) ABSTRACT

Disclosed are a display panel and method of manufacturing the same, the display panel including a substrate, an isolation structure, and a light-emitting layer. The isolation structure defines light-transmitting openings in an enclosing manner to increase the transmittance of the display panel. At least part of the light-transmitting openings are disposed between adjacent light-emitting units of the same color, and the isolation structure and the light-transmitting openings are arranged in a similar manner between the light-emitting units of the same color, which improves the uniformity of the arrangement of the light-transmitting openings between adjacent light-emitting units of the same color, ameliorates poor display of the display panel, such as mura, and enhances the display effect of the display panel, thereby improving the use performance of OLED display products.

### CROSS-REFERENCE TO RELATED APPLICATIONS

The present application claims priority to the Chinese Patent Application No. CN 202411847045.2, filed on Dec. 13, 2024, and the entire contents of the aforementioned application are hereby incorporated by reference in its entirety.

### FIELD

The present application relates to the field of display, and in particular to a display panel and method of manufacturing the same.

### BACKGROUND

Organic light-emitting diodes (OLEDs) and flat panel display devices based on technologies such as light-emitting diodes (LEDs) have been widely applied to various consumer electronics such as mobile phones, televisions, notebook computers and desktop computers and predominate in display devices thanks to their advantages such as high image quality, energy efficiency, slim design and a wide range of applications.

During the preparation of conventional display panels, light-emitting pixel patterning is usually implemented by means of a fine metal mask (FMM). FMM technology is mature and has rich experience in mass production. However, FMM technology also has problems such as limited accuracy, high development costs, and long development cycle. Fine metal mask-free technology eliminates the limitations of traditional OLED processes on the size, resolution, and other screen performances of a display screen, and has the advantages of high performance, full-range size, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference.

However, the use performance of conventional OLED display products needs to be improved.

### SUMMARY

One or more embodiments of the present application provide a display panel and method of manufacturing the same, with the aim of improving the use performance of OLED display products.

One or more embodiments of the present application provide a display panel, including: a substrate; an isolation structure on a side of the substrate, the isolation structure defining a plurality of isolation openings and a plurality of light-transmitting openings in an enclosing manner; and a light-emitting layer on a side of the substrate, the light-emitting layer including a plurality of light-emitting units located at least partially within the isolation openings, and at least one orthographic projection of at least part of the light-transmitting openings on the substrate being positioned between orthographic projections of adjacent light-emitting units of the same color on the substrate.

One or more embodiments of the present application provide a display panel, the display panel further including: a substrate;
an isolation structure on a side of the substrate, the isolation structure defining a plurality of isolation openings and a plurality of light-transmitting openings in an enclosing manner; and a light-emitting layer on a side of the substrate, the light-emitting layer including a plurality of light-emitting units located at least partially within the isolation openings, and a difference between distances between at least part of the light-transmitting openings and adjacent light-emitting units of the same color being less than or equal to 1.5 μm.

One or more embodiments of the present application provide a method of manufacturing a display panel, the method including:
preparing on a substrate an isolation structure, the isolation structure defining a plurality of isolation openings and a plurality of light-transmitting openings in an enclosing manner; and
preparing on the substrate a light-emitting layer, the light-emitting layer including a plurality of light-emitting units located at least partially within the isolation opening, and at least one orthographic projection of at least part of the light-transmitting openings on the substrate being positioned between orthographic projections of adjacent light-emitting units of the same color on the substrate.

According to the display panel of the embodiment of the present application, the display panel includes a substrate, an isolation structure, and a light-emitting layer. When the light-emitting layer is prepared, the light-emitting layer causes a large drop at an edge of the isolation structure, and is difficult to connect, resulting in breakage. The light-emitting layer breaks to form light-emitting units which are disconnected from each other and which are located in the isolation openings, which eliminates the need for a precision mask plate, reducing the development and use of the precision mask plate and lowering the preparation cost. The isolation structure defines light-transmitting openings in an enclosing manner to increase the transmittance of the display panel. At least part of the light-transmitting openings are disposed between adjacent light-emitting units of the same color, and the isolation structure and the light-transmitting openings are arranged in a similar manner between the light-emitting units of the same color, which improves the uniformity of the arrangement of the light-transmitting openings between adjacent light-emitting units of the same color, ameliorates poor display of the display panel, such as mura, and enhances the display effect of the display panel, thereby improving the use performance of OLED display products.

### BRIEF DESCRIPTION OF THE DRAWINGS

Other embodiments of the present application will become more clear upon reading the following detailed description of non-limiting embodiments with reference to the accompanying drawings, where identical or similar reference signs indicate identical or similar features and the drawings are not necessarily drawn to scale.

FIG. 1 is a schematic partial top view of a display panel according to one or more embodiments of the present application;

FIG. 2 is a partial sectional view of a display panel according to one or more embodiments of the present application;

FIG. 3 is a partial sectional view of a display panel according to one or more embodiments;

FIG. 4 is a partial sectional view of a display panel according to one or more embodiments;

FIG. 5 is a schematic partial top view of a display panel according to one or more embodiments;

FIG. 6 is a schematic partial top view of a display panel according to one or more embodiments;

FIG. 7 is a partial sectional view of a display panel according to one or more embodiments;

FIG. 8 is a partial sectional view of a display panel according to one or more embodiments;

FIG. 9 is a partial sectional view of a display panel according to one or more embodiments; and

FIG. 10 is a flowchart of a method of manufacturing a display panel according to one or more embodiments of the present application.

### LIST OF REFERENCE SIGNS

10. DISPLAY PANEL;
100. Substrate;
200. Isolation structure; 210. First layer; 220. Second layer; 230. Third layer; 240.
Isolation opening; 250. Light-transmitting opening; 260. First light-transmitting opening;
270. Second light-transmitting opening; 280. Third light-transmitting opening;
300. Light-emitting layer; 301. Light-emitting device; 310. Light-emitting unit; 320. First light-emitting unit; 321. First unit; 322. Second unit; 330. Second light-emitting unit;
340. Third light-emitting unit;
400. First electrode;
500. Pixel defining layer; 510. Pixel opening; 520. Second electrode;
D1. First distance; D2. Second distance; D3. Third distance; D4. Fourth distance;
X. First direction; Y. Second direction.

### DETAILED DESCRIPTION OF THE EMBODIMENTS

Features and exemplary embodiments of the present application will be described in detail below. In order to make the embodiments of the present application clearer, the present application will be further described in detail below with reference to the accompanying drawings and specific embodiments. It should be understood that the specific embodiments described herein are merely configured to explain the present application and are not configured to limit the present application. The present application may be implemented without some of these specific details. The following description of the embodiments is merely to provide a better understanding of the present application by illustrating examples of the present application.

Terms such as “first” and “second” in the description, claims, and above drawings of the present application are used to distinguish between similar objects and are not necessarily used to describe a particular order or sequence. It is to be understood that data used in this manner is interchangeable in appropriate cases and the embodiments of the present application described herein can also be implemented in an order not illustrated or described herein. In addition, terms “comprising”, “including”, and any variation thereof are intended to encompass a non-exclusive inclusion. For example, a process, method, system, product, or device that includes a series of steps or units not only includes the expressly listed steps or units, but may also include other steps or units that are not expressly listed or are inherent to such a process, method, product, or device.

When describing the structure of a component, when a layer or area is referred to as being “above” or “above” another layer or area, it can mean being directly above another layer or area, or having other layers or areas between it and another layer or area. Moreover, if the component is flipped over, this layer, one area will be located “below” or “below” another layer, another area.

One or more embodiments of the present application provide a display panel, a display device and a method for preparing the display panel. Various embodiments of the display panel, the display device and the method for preparing the display panel will be illustrated below with reference to the drawings.

The embodiments of the present application provide a display panel, which may be an organic light-emitting diode (OLED) display panel.

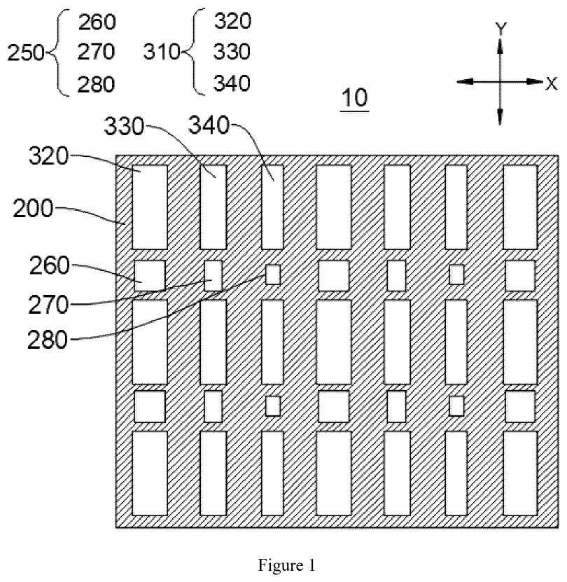

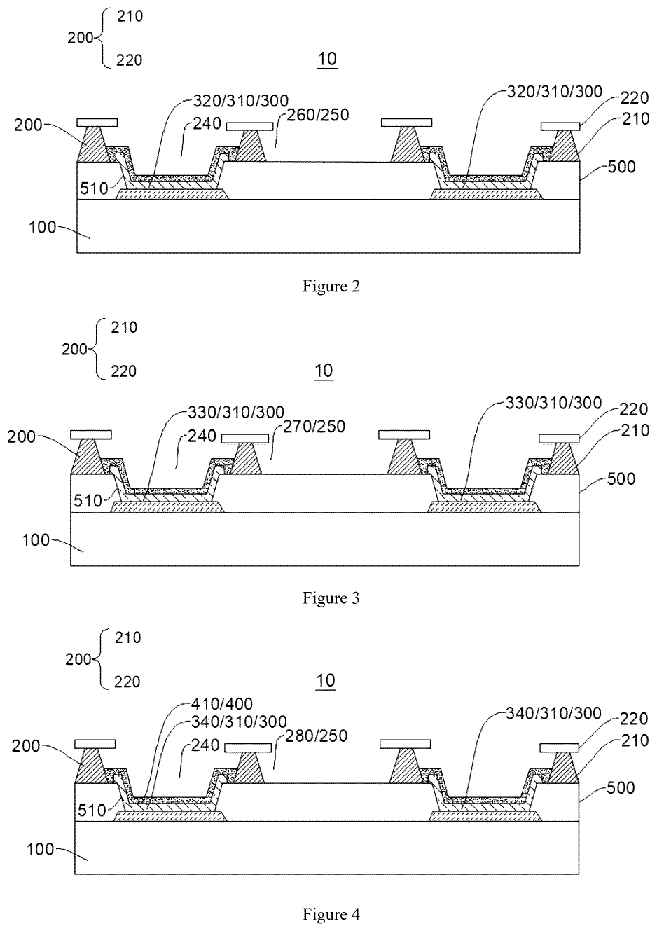

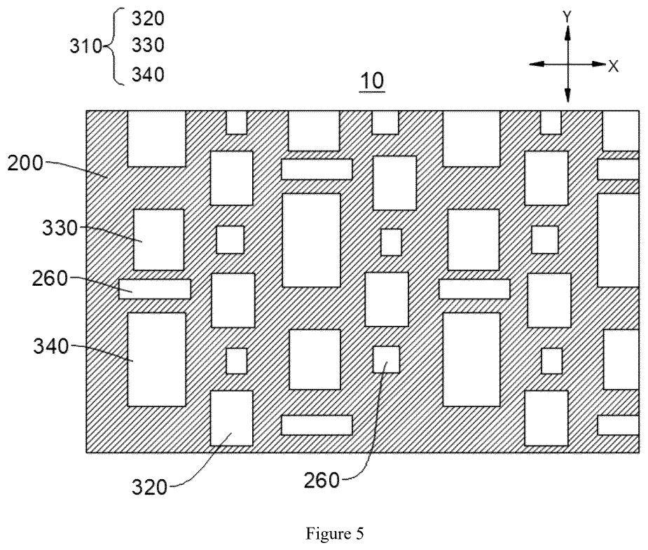

Referring to FIGS. 1 to 5 together, FIG. 1 is a schematic partial top view of a display panel according to one or more embodiments of the present application; FIG. 2 is a partial sectional view of a display panel according to one or more embodiments of the present application; FIG. 3 is a partial sectional view of a display panel according to one or more embodiments; FIG. 4 is a partial sectional view of a display panel according to one or more embodiments; and FIG. 5 is a schematic partial top view of a display panel according to one or more embodiments.

As shown in FIGS. 1 to 5, an embodiment of the present application provides a display panel 10, including: a substrate 100; an isolation structure 200 on a side of the substrate 100, the isolation structure 200 defining a plurality of isolation openings 240 and a plurality of light-transmitting openings 250 in an enclosing manner; and a light-emitting layer 300 on a side of the substrate 100, the light-emitting layer 300 including a plurality of light-emitting units 310 located at least partially within the isolation openings 240, and at least one orthographic projection of at least part of the light-transmitting openings 250 on the substrate 100 being positioned between orthographic projections of adjacent light-emitting units 310 of the same color on the substrate 100.

According to the display panel 10 of the embodiment of the present application, the display panel 10 includes a substrate 100, an isolation structure 200, and a light-emitting layer 300. When the light-emitting layer 300 is prepared, the light-emitting layer 300 causes a large drop at an edge of the isolation structure 200, and is difficult to connect, resulting in breakage. The light-emitting layer 300 breaks to form light-emitting units 310 which are disconnected from each other and which are located in the isolation openings 240, which eliminates the need for a precision mask plate, reducing the development and use of the precision mask plate and lowering the preparation cost. The isolation structure 200 defines light-transmitting openings 250 in an enclosing manner to increase the transmittance of the display panel 10. At least part of the light-transmitting openings 250 are disposed between adjacent light-emitting units 310 of the same color, and the isolation structure 200 and the light-transmitting openings 250 are arranged in a similar manner between the light-emitting units 310 of the same color, which improves the uniformity of the arrangement of the light-transmitting openings 250 between adjacent light-emitting units 310 of the same color, ameliorates poor display of the display panel 10, such as mura, and enhances the display effect of the display panel 10, thereby improving the use performance of OLED display products.

The substrate 100 may be arranged in a variety of ways, for example, the substrate 100 may include a base substrate and an array substrate disposed on the base substrate. For example, the substrate 100 is the base substrate. For example, the substrate 100 includes a buffer layer, a support plate, etc. on a side facing away from the base substrate.

The composition, preparation and the like of the isolation structure 200 are further described in patents CN118251982A, 202410864269.8, PCT/CN2024/098407, PCT/CN2024/102783, PCT/CN2024/098217, PCT/CN2024/099419, PCT/CN2024/099072, CN117979755A, CN117998900A, CN117062489A, CN117580403A, CN116583155A, CN116669477A, CN117396039A, CN116669480A, CN116600606A, CN117500332A for reference.

As shown in FIGS. 1 and 2, in one or more embodiments, the plurality of light-emitting units 310 includes a plurality of first light-emitting unit 320, and the plurality of light-transmitting openings 250 includes one or more first light-transmitting openings 260, an orthographic projection of the first light-transmitting opening 260 on the substrate 100 being positioned between orthographic projections of adjacent first light-emitting units 320 on the substrate 100.

In these embodiments, the first light-transmitting opening 260 is disposed between adjacent first light-emitting units 320 and the isolation structure 200 and the light-transmitting opening 250 between the adjacent first light-emitting units 320 are disposed in a similar manner, which improves the uniformity of the arrangement of the first light-transmitting openings 260 between the adjacent first light-emitting units 320, and ameliorates poor display of the display panel 10, such as mura.

In one or more embodiments, one or more first light-transmitting openings 260 include a plurality of first light-transmitting openings 260, the first light-transmitting openings 260 have the same size, and the first light-transmitting opening 260 has the same area, side length and shape, which further improves the uniformity of the arrangement of the first light-transmitting openings 260. In process steps or some uncontrollable cases, each of the first light-transmitting openings also has the same size within a tolerance range of ±3 μm.

As shown in FIGS. 1 and 3, in one or more embodiments, the plurality of light-emitting units 310 further includes a plurality of second light-emitting units 330 spaced from the first light-emitting unit 320, and the plurality of light-transmitting openings 250 includes one or more second light-transmitting openings 270, an orthographic projection of the second light-transmitting opening 270 on the substrate 100 being positioned between orthographic projections of adjacent second light-emitting units 330 on the substrate 100.

In one or more embodiments, the second light-transmitting opening 270 is disposed between the adjacent second light-emitting units 330 and the isolation structure 200 and the light-transmitting opening 250 between the adjacent second light-emitting units 330 are disposed in a similar manner, which improves the uniformity of the arrangement of the second light-transmitting openings 270 between the adjacent second light-emitting units 330, and ameliorates poor display of the display panel 10, such as mura.

In one or more embodiments, one or more second light-transmitting openings 270 include a plurality of second light-transmitting openings 270, the second light-transmitting openings 270 have the same size (±5 μm), and the second light-transmitting opening 270 has the same area, side length, and shape, which further improves the uniformity of the arrangement of the second light-transmitting openings 270.

As shown in FIGS. 1 and 4, in one or more embodiments, the plurality of light-emitting unit 310 further includes a plurality of third light-emitting units 340 spaced from the first light-emitting unit 320 and the second light-emitting unit 330, and the plurality of light-transmitting openings 250 includes one or more third light-transmitting openings 280, an orthographic projection of the third light-transmitting opening 280 on the substrate 100 being positioned between orthographic projections of adjacent third light-emitting units 340 on the substrate 100.

In one or more embodiments, the third light-transmitting opening 280 is disposed between the adjacent third light-emitting units 340 and the isolation structure 200 and the light-transmitting opening 250 between the adjacent third light-emitting units 340 are disposed in a similar manner, which improves the uniformity of the arrangement of the third light-transmitting openings 280 between the adjacent third light-emitting units 340, and ameliorates poor display of the display panel 10, such as mura.

In one or more embodiments, one or more third light-transmitting openings 280 include a plurality of third light-transmitting openings 280, the third light-transmitting openings 280 have the same size (±5 μm), and the third light-transmitting opening 280 has the same area, side length, and shape, which further improves the uniformity of the arrangement of the second light-transmitting openings 270.

In one or more embodiments, the first light-emitting unit 320 is a green light-emitting unit, the second light-emitting unit 330 is a red light-emitting unit, and the third light-emitting unit 340 is a blue light-emitting unit.

In one or more embodiments, the light-transmitting openings 250 are uniformly distributed in a first direction X, or the light-transmitting openings 250 are uniformly distributed in a second direction Y, the first direction X intersecting with the second direction Y. For example, the light-transmitting openings 250 are uniformly distributed in a first direction X, the light-transmitting openings 250 are uniformly distributed in a second direction Y. The light-transmitting openings 250 being uniformly distributed in the first direction X means that the light-transmitting openings 250 are uniformly distributed in the first direction X in a spaced manner, and the light-transmitting openings 250 being uniformly distributed in the second direction Y means that the light-transmitting openings 250 are uniformly distributed in the second direction Y in a spaced manner, which further improves the uniformity of the arrangement of the light-transmitting openings 250.

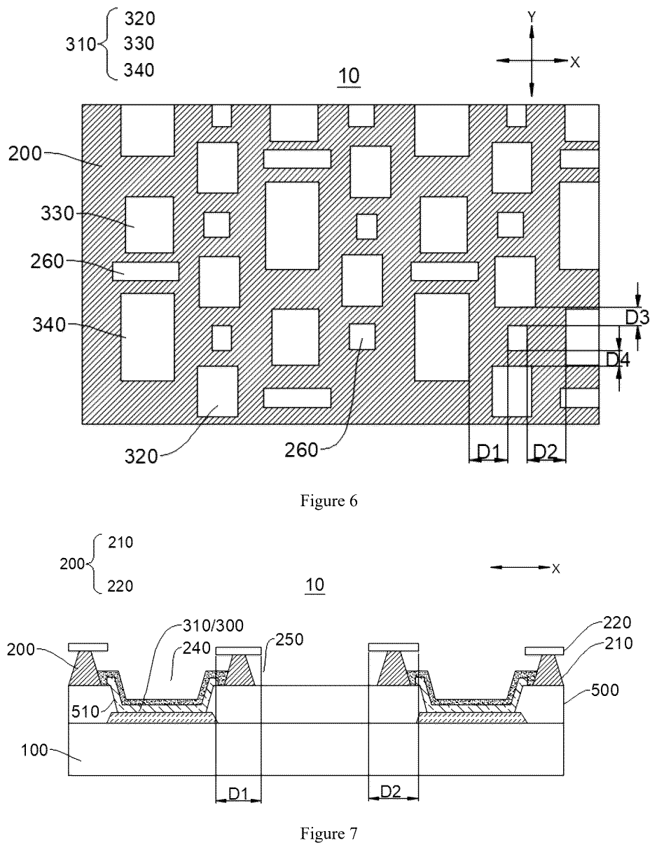

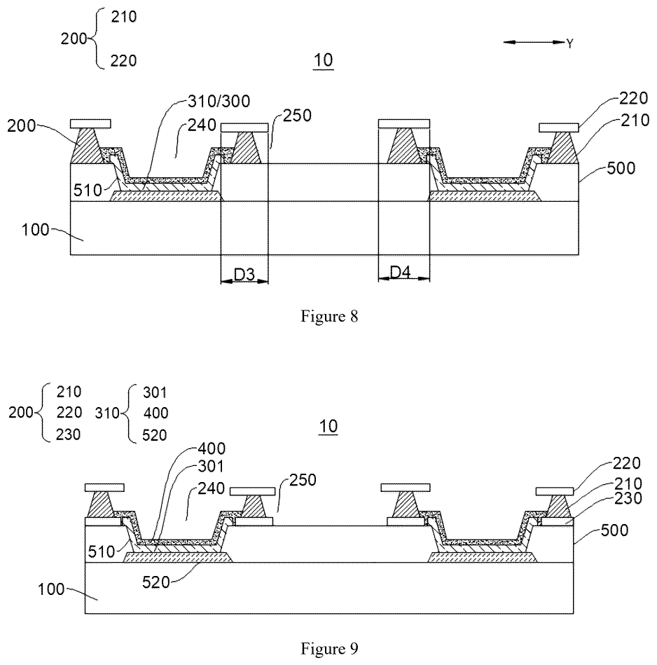

Referring to FIGS. 6 to 8, FIG. 6 is a schematic partial top view of a display panel according to yet another embodiment; FIG. 7 is a partial sectional view of a display panel according to still yet another embodiment; and FIG. 8 is a partial sectional view of a display panel according to a still further embodiment.

In one or more embodiments, a difference between distances between at least part of the light-transmitting openings 250 and adjacent light-emitting units 310 of the same color is less than or equal to 1.5 μm.

As shown in FIGS. 6 and 7, in one or more embodiments, the distance between at least part of the light-transmitting openings 250 and adjacent light-emitting units 310 of the same color is equal. For example, in one or more embodiments, a minimum distance between the light-transmitting opening 250 and the light-emitting unit 310 located on one side of the light-transmitting opening 250 in the first direction X is a first distance D1, and the first distance D1 corresponding to at least part of the light-transmitting openings 250 between the adjacent light-emitting units 310 of the same color is equal or the difference between the first distances is less than or equal to 1.5 μm. For example, the difference between the first distances D1 corresponding to at least part of the light-transmitting openings 250 is less than or equal to 1.5 μm.

In one or more embodiments, the distance between an orthographic projection of the light-transmitting opening 250 on the substrate 100 and an orthographic projection of the light-emitting unit 310 at one side of the light-transmitting opening in the first direction X on the substrate 100 is equal, which improves the uniformity of the arrangement of the light-transmitting openings 250 in the first direction X. For example, the distance between the first light-emitting unit 320 and one side of the first light-transmitting opening 260 located between adjacent first light-emitting units 320 in the first direction X is equal, or the distance between the second light-emitting unit 330 and one side of the second light-transmitting opening 270 located between adjacent second light-emitting units 330 in the first direction X is equal, or the distance between the third light-emitting unit 340 and one side of the third light-transmitting opening 280 located between adjacent third light-emitting units 340 in the first direction X is equal.

As shown in FIGS. 6 and 7, in one or more embodiments, a minimum distance between the light-transmitting opening 250 and the light-emitting unit 310 located on the other side of the light-transmitting opening 250 in the first direction X is a second distance D2, and the second distance D2 corresponding to at least part of the light-transmitting openings 250 between adjacent light-emitting units 310 of the same color is equal or the difference between the second distances is less than or equal to 1.5 μm. For example, the difference between the second distances D2 corresponding to at least part of the light-transmitting openings 250 is less than or equal to 1.5 μm.

In one or more embodiments, the distance between the orthographic projection of the light-transmitting opening 250 on the substrate 100 and an orthographic projection of the light-emitting unit 310 at the other side of the light-transmitting opening in the first direction X on the substrate 100 is equal, which further improves the uniformity of the arrangement of the light-transmitting openings 250 in the first direction X. For example, the distance between the first light-emitting unit 320 and the other side of the first light-transmitting opening 260 located between adjacent first light-emitting units 320 in the first direction X is equal, or the distance between the second light-emitting unit 330 and the other side of the second light-transmitting opening 270 located between adjacent second light-emitting units 330 in the first direction X is equal, or the distance between the third light-emitting unit 340 and the other side of the third light-transmitting opening 280 located between adjacent third light-emitting units 340 in the first direction X is equal.

As shown in FIGS. 6 and 8, in one or more embodiments, a minimum distance between the light-transmitting opening 250 and the light-emitting unit 310 located on one side of the light-transmitting opening 250 in the second direction Y is a third distance D3, and the third distance D3 corresponding to at least part of the light-transmitting openings 250 between adjacent light-emitting units 310 of the same color is equal or the difference between the third distances is less than or equal to 1.5 μm. For example, the difference between the third distances D3 corresponding to at least part of the light-transmitting openings 250 is less than or equal to 1.5 μm.

In one or more embodiments, the distance between an orthographic projection of the light-transmitting opening 250 on the substrate 100 and an orthographic projection of the light-emitting unit 310 at one side of the light-transmitting opening in the second direction Y on the substrate 100 is equal, which improves the uniformity of the arrangement of the light-transmitting openings 250 in the second direction Y. For example, the distance between the first light-emitting unit 320 and one side of the first light-transmitting opening 260 located between adjacent first light-emitting units 320 in the second direction Y is equal, or the distance between the second light-emitting unit 330 and one side of the second light-transmitting opening 270 located between adjacent second light-emitting units 330 in the second direction Y is equal, or the distance between the third light-emitting unit 340 and one side of the third light-transmitting opening 280 located between adjacent third light-emitting units 340 in the second direction Y is equal.

As shown in FIGS. 6 and 8, in one or more embodiments, a minimum distance between the light-transmitting opening 250 and the light-emitting unit 310 located on the other side of the light-transmitting opening 250 in the second direction Y is a fourth distance D4, and the fourth distance D4 corresponding to at least part of the light-transmitting openings 250 between adjacent light-emitting units 310 of the same color is equal or the difference between the fourth distances is less than or equal to 1.5 μm. For example, the difference between the fourth distances D4 corresponding to at least part of the light-transmitting openings 250 is less than or equal to 1.5 μm.

In one or more embodiments, the distance between an orthographic projection of the light-transmitting opening 250 on the substrate 100 and an orthographic projection of the light-emitting unit 310 at the other side of the light-transmitting opening in the second direction Y on the substrate 100 is equal, which further improves the uniformity of the arrangement of the light-transmitting openings 250 in the second direction Y. For example, the distance between the first light-emitting unit 320 and the other side of the first light-transmitting opening 260 located between adjacent first light-emitting units 320 in the second direction Y is equal, or the distance between the second light-emitting unit 330 and the other side of the second light-transmitting opening 270 located between adjacent second light-emitting units 330 in the second direction Y is equal, or the distance between the third light-emitting unit 340 and the other side of the third light-transmitting opening 280 located between adjacent third light-emitting units 340 in the second direction Y is equal.

In one or more embodiments, when the distance between an adjacent light-transmitting unit 310 and some type of light-transmitting opening 250 (e.g., a first opening 261, a second opening 262, a third opening 263, the first light-transmitting opening 260, the second light-transmitting opening 270 or the third light-transmitting opening 280) located between the light-emitting units 310 of the same color is equal in each direction, this type of light-transmitting opening 250 forms a light-transmitting unit, the light-transmitting unit may be translated and the distance between a single light-transmitting opening 250 and an adjacent light-emitting unit 310 changes, but the distance between each light-transmitting opening 250 and the corresponding light-emitting unit 310 is still equal.

As shown in FIGS. 6 to 8, in one or more embodiments, the minimum distance between the light-transmitting opening 250 and the light-emitting unit 310 located on one side of the light-transmitting opening 250 in the first direction X is the first distance D1, and the minimum distance between the light-transmitting opening 250 and the light-emitting unit 310 located on the other side of the light-transmitting opening 250 in the first direction X is the second distance D2, the difference between the first distance D1 and the second distance D2 being less than or equal to 1.5 μm; and the minimum distance between the light-transmitting opening 250 and the light-emitting unit 310 located on one side of the light-transmitting opening 250 in the second direction Y is the third distance D3, and the minimum distance between the light-transmitting opening 250 and the light-emitting unit 310 located on the other side of the light-transmitting opening 250 in the second direction Y is the fourth distance D4, the difference between the third distance D3 and the fourth distance D4 being less than or equal to 1.5 μm. That is, the difference in width of portions of the isolation structures 200 on both sides of the light-transmitting opening 250 in the first direction is less than or equal to 1.5 μm, and the difference in width of portions of the isolation structure 200 on both sides of the light-transmitting opening 250 in the second direction Y is less than or equal to 1.5 μm, the width of the portion of the isolation structure 200 being the dimension of the isolation structure 200 in the direction from the light-transmitting opening 250 pointing toward the isolation opening 240.

In one or more embodiments, the difference in width of the portions of the isolation structures 200 on both sides of the light-transmitting opening 250 is less than or equal to 1.5 μm to reduce the difference in width of the isolation structures 200 located on both sides of the light-transmitting opening 250, and the difference in distribution of the isolation structures 200 between the light-transmitting openings 250 and the adjacent light-emitting units 310 is reduced, thereby improving the uniformity of distribution of the isolation structures 200 and the light-transmitting openings 250, and ameliorating poor display of the display panel 10, such as mura.

In one or more embodiments, the minimum distance between the light-transmitting opening 250 and the light-emitting unit 310 located on one side of the light-transmitting opening 250 in the first direction X is the first distance D1, and the minimum distance between the light-transmitting opening 250 and the light-emitting unit 310 located on the other side of the light-transmitting opening 250 in the first direction X is the second distance D2, the first distance D1 being equal to the second distance D2. That is, widths of the portions of the isolation structure 200 on both sides of the light-transmitting opening 250 in the first direction X are equal.

In one or more embodiments, the difference in width of the isolation structure 200 located on both sides of the light-transmitting opening 250 in the first direction is further reduced, thereby further improving the uniformity of distribution of the isolation structures 200 and the light-transmitting openings 250, and ameliorating poor display of the display panel 10, such as mura.

In one or more embodiments, the minimum distance between the light-transmitting opening 250 and the light-emitting unit 310 located on one side of the light-transmitting opening 250 in the second direction Y is the third distance D3, and the minimum distance between the light-transmitting opening 250 and the light-emitting unit 310 located on the other side of the light-transmitting opening 250 in the second direction Y is the fourth distance D4, the third distance D3 being equal to the fourth distance D4. That is, widths of the portions of the isolation structure 200 on both sides of the light-transmitting opening 250 in the second direction Y are equal.

In one or more embodiments, the difference in width of the isolation structure 200 located on both sides of the light-transmitting opening 250 in the second direction Y is further reduced, thereby further improving the uniformity of distribution of the isolation structures 200 and the light-transmitting openings 250, and ameliorating poor display of the display panel 10, such as mura.

In one or more embodiments, the plurality of light-transmitting openings 250 are arranged at intervals in the first direction X in which a difference between a distance between at least part of two adjacent light-transmitting openings 250 and a distance between another two adjacent light-transmitting openings 250 is less than or equal to 1.5 μm.

In one or more embodiments, at least part of the light-transmitting openings 250 are arranged at intervals in the first direction X, the distance between two adjacent light-transmitting openings 250 being equal in the first direction X.

In one or more embodiments, the plurality of light-transmitting openings 250 arranged in the first direction X are equally spaced and the light-transmitting openings 250 are more uniformly distributed in the first direction X, thereby improving the uniformity of distribution of the light-transmitting openings 250 in the first direction X.

In one or more embodiments, the plurality of light-transmitting openings 250 are arranged at intervals in the second direction Y in which a difference between a distance between at least part of two adjacent light-transmitting openings 250 and a distance between another two adjacent light-transmitting openings 250 is less than or equal to 1.5 μm.

In one or more embodiments, at least part of the light-transmitting openings 250 are arranged at intervals in the second direction Y, the distance between two adjacent light-transmitting openings 250 being equal in the second direction Y.

In one or more embodiments, the plurality of light-transmitting openings 250 arranged in the second direction Y are equally spaced and the light-transmitting openings 250 are more uniformly distributed in the second direction Y, thereby improving the uniformity of distribution of the light-transmitting openings 250 in the first direction X.

In one or more embodiments, the distance between two adjacent first light-transmitting openings 260 is equal in the first direction X, or the distance between two adjacent first light-transmitting openings 260 is equal in the second direction Y. For example, the distance between two adjacent first light-transmitting openings 260 is equal in the first direction X, and the distance between two adjacent first light-transmitting openings 260 is equal in the second direction Y.

In one or more embodiments, the distance between two adjacent second light-transmitting openings 270 is equal in the first direction X, or the distance between two adjacent second light-transmitting openings 270 is equal in the second direction Y. For example, the distance between two adjacent second light-transmitting openings 270 is equal in the first direction X, and the distance between two adjacent second light-transmitting openings 270 is equal in the second direction Y.

In one or more embodiments, the distance between two adjacent third light-transmitting openings 280 is equal in the first direction X, or the distance between two adjacent third light-transmitting openings 280 is equal in the second direction Y. For example, the distance between two adjacent third light-transmitting openings 280 is equal in the first direction X, and the distance between two adjacent third light-transmitting openings 280 is equal in the second direction Y.

In one or more embodiments, a minimum distance between the light-transmitting opening 250 and the adjacent isolation opening 240 ranges from 2.5 μm to 20 μm. That is, a minimum distance between an orthographic projection of the light-transmitting opening 250 on the substrate 100 and an orthographic projection of the adjacent isolation opening 240 on the substrate 100 ranges from 2.5 μm to 20 μm. For example, the minimum distance between the light-transmitting opening 250 and the isolation opening 240 is 2.5 μm, 5 μm, 10 μm, 20 μm.

In one or more embodiments, the distance between the light-transmitting opening 250 and the adjacent isolation opening 240 is greater than or equal to 2.5 μm, which may relieve the problems of high process precision requirements and preparation difficulty due to the distance between the light-transmitting opening 250 and the adjacent isolation opening 240 being too small. The distance between the light-transmitting opening 250 and the adjacent isolation opening 240 is less than or equal to 20 μm, which may relieve the problems of a smaller area setting for the isolation opening 240 and a lower opening rate of the display panel 10 due to the distance between the light-transmitting opening 250 and the adjacent isolation opening 240 being too large.

In one or more embodiments, the isolation structure 200 includes a first layer 210 and a second layer 220 on a side of the first layer 210 facing away from the substrate 100, an orthographic projection of the first layer 210 on the substrate 100 being located within an orthographic projection of the second layer 220 on the substrate 100.

In one or more embodiments, the isolation structure 200 includes the first layer 210 and the second layer 220 on the side of the first layer 210 facing away from the substrate 100, the first layer 210 and the second layer 220 being stacked to form the isolation structure 200, an orthographic projection of the first layer 210 disposed close to the substrate 100 on the substrate 100 is within an orthographic projection of the second layer 220 on the substrate 100, the area of the second layer 220 is larger than the area of the first layer 210, and the second layer 220 covers the surface of the first layer 210 close to the second layer 220, in which case the first layer 210 is recessed with respect to the second layer 220 in a direction away from the isolation opening 240. When the light-emitting layer 300 is prepared, the light-emitting layer 300 causes a large drop at an edge of the isolation structure 200, the first layer 210 is recessed with respect to the second layer 220, and the light-emitting layer 300 is difficult to connect at the edge of the isolation structure 200, resulting in breakage. The light-emitting layer 300 breaks to form light-emitting units 310 that are disconnected from each other, thereby reducing crosstalk of carriers in the light-emitting layer 300, and improving the display effect of the display panel 10; and the light-emitting unit 310 may be prepared without the use of a precision mask plate, reducing the development and use of the precision mask plate and lowering the preparation cost.

In one or more embodiments, the first layer 210 includes a conductive material, for example, the first layer 210 includes a non-metallic conductive material or a metallic conductive material.

In one or more embodiments, the second layer 220 includes a conductive material or an insulation material.

In one or more embodiments, the second layer 220 includes a conductive material, for example, the second layer 220 includes a non-metallic conductive material or a metallic conductive material. When the second layer 220 is a non-metallic conductive material or an insulation material, during wet etching of the first layer 210 with an etching solution, the second layer 220 is difficult to etch, thereby making it easier for the first layer 210 to be recessed relative to the second layer 220.

In one or more embodiments, the first layer 210 and the second layer 220 each include a metallic material, and the material of the first layer 210 and the second layer 220 is different.

In one or more embodiments, when the first layer 210 and the second layer 220 are both metallic materials, the first layer 210 may be wet etched with an etching solution, and the etching solution is provided to enable an etching rate of the second layer 220 to be less than an etching rate of the first layer 210. Since the etching rate of the first layer 210 is large, when wet etching is performed with an etching solution, the first layer 210 is etched faster even though the second layer 220 is subjected to some etching, which causes the first layer 210 to be recessed relative to the second layer 220.

Referring to FIG. 9, FIG. 9 is a partial sectional view of a display panel according to a still further embodiment.

As shown in FIG. 9, in one or more embodiments, the isolation structure 200 further includes a third layer 230 on a side of the first layer 210 facing the substrate 100, and an orthographic projection of the first layer 210 on the substrate 100 is located within an orthographic projection of the third layer 230 on the substrate 100.

In one or more embodiments, since the first layer 210 is provided in order to obtain a recessed arrangement, the first layer 210 has a faster etching rate relative to the second layer 220 and the third layer 230 during etching, forming a recessed first layer 210. Since the etching rate of the first layer 210 is higher, more waste is generated during the etching and is likely to enter other locations of the display panel 10, thus causing an adverse effect. After the third layer 230 is provided, the first layer 210 may be better adhered to the third layer 230, and the generated etching waste falls on the third layer 230 to facilitate removal.

In one or more embodiments, the light-emitting layer 300 includes an electron injection layer (EIL), an electron transport layer (ETL), a light-emitting material layer, a hole injection layer (HIL) and a hole transport layer (HTL).

In one or more embodiments, the display panel 10 further includes: a first electrode layer 400 located on a side of the light-emitting layer 300 facing away from the substrate 100, the first electrode layer 400 including a first electrode 400 located in the isolation opening 240, and the first electrode 400 being electrically connected to the isolation structure 200.

In one or more embodiments, the isolation structure 200 separates the first electrode layer 400 to form first electrodes 400 spaced apart from each other, and the first electrodes 400 spaced apart from each other are electrically connected through the isolation structure 200 to form a continuous electrode to ensure normal light emission of the light-emitting unit 310.

In one or more embodiments, the display panel 10 further includes: a pixel defining layer 500 on a side of the substrate 100, the pixel defining layer 500 defining a plurality of pixel openings 510 in an enclosing manner, and the pixel openings 510 communicating with the isolation openings 240.

In one or more embodiments, the pixel defining layer 500 defines a pixel opening 510 in an enclosing manner to set the light-emitting unit 310 to achieve normal light emission of the light-emitting unit 310. In addition, a pixel defining portion 510 defines a set area of each light-emitting unit 310, reducing color cast between the light-emitting units 310.

As shown in FIG. 9, in one or more embodiments, the light-emitting unit 310 further includes a second electrode 520 between the substrate 100 and the pixel defining layer 500, a portion of the second electrode 520 being exposed by the pixel opening 510.

In one or more embodiments, the isolation structure 200 is disposed on the pixel defining layer 500.

In one or more embodiments, the light-emitting unit 310 further includes: a light-emitting device 301 disposed on the second electrode 520 and a first electrode 400 disposed on the light-emitting device 301, the first electrode 400 being electrically connected to the isolation structure 200.

In one or more embodiments, one of the second electrode 520 and the first electrode 400 acts as an anode of the light-emitting unit 310 and the other acts as a cathode of the light-emitting unit 310. The embodiment of the present application is exemplified by taking the second electrode 520 as the anode of the light-emitting unit 310, and the first electrode 400 as the cathode of the light-emitting unit 310.

In one or more embodiments of the present application provides a display panel 10, the display panel 10 further including: a substrate 100; an isolation structure 200 on a side of the substrate 100, the isolation structure 200 defining a plurality of isolation openings 240 and a plurality of light-transmitting openings 250 in an enclosing manner; and a light-emitting layer 300 on a side of the substrate 100, the light-emitting layer 300 including a plurality of light-emitting units 310 located at least partially within the isolation openings 240, and the distance between at least part of the light-transmitting openings 250 and adjacent light-emitting units 310 of the same color being equal.

According to the display panel 10 of the embodiment of the present application, the display panel 10 includes a substrate 100, an isolation structure 200, and a light-emitting layer 300. When the light-emitting layer 300 is prepared, the light-emitting layer 300 causes a large drop at an edge of the isolation structure 200, and is difficult to connect, resulting in breakage. The light-emitting layer 300 breaks to form light-emitting units 310 which are disconnected from each other and which are located in the isolation openings 240, which eliminates the need for a precision mask plate, reducing the development and use of the precision mask plate and lowering the preparation cost. The isolation structure 200 defines light-transmitting openings 250 in an enclosing manner to increase the transmittance of the display panel 10. The distance between at least part of the light-transmitting openings 250 and adjacent light-emitting units 310 of the same color is equal, and the light-transmitting openings 250 and the corresponding light-emitting units 310 are arranged in a relatively uniform manner, which improves the uniformity of the arrangement of the light-transmitting openings 250, and ameliorates poor display of the display panel 10, such as mura.

As for the structural design in this embodiment, it can be applied to other display panels 10, which can be selected according to actual situations, and this is not specifically limited in the present application. For the distances referred to in this application as “same” or “equal”, and according to the process steps or some uncontrollable cases, it is one embodiment of the present application as long as it is within the tolerance range of ±1.5 μm.

In one or more embodiment of the present application further provides a display device, including a display panel 10 of any of the above embodiments disclosure. Since the display device according to the embodiment of the present application includes the display panel 10 of any of the above embodiments of the disclosure, the display device according to the embodiment of the present application has the beneficial effects of the display panel 10 of any of the above embodiments of the disclosure, which will not be described in detail here.

The display device in the embodiments of the present application includes, but is not limited to devices having a display function, such as a cell phone, a personal digital assistant (PDA), a tablet computer, an e-book, a television, an access control, a smart fixed-line telephone, or a control console.

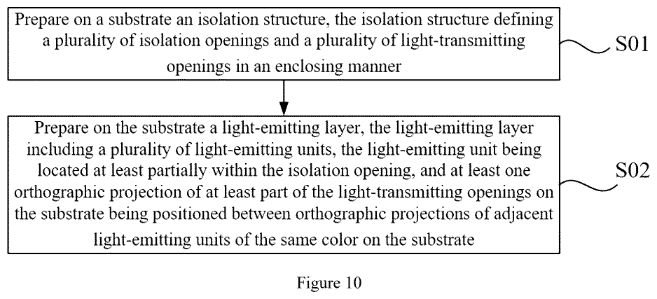

Referring to FIG. 10, FIG. 10 is a flowchart of a method of manufacturing a display panel according to an embodiment of the present application.

As shown in FIG. 10, an embodiment of the present application provides a method of manufacturing a display panel 10, the method including:
at step S01, preparing on a substrate an isolation structure, the isolation structure defining a plurality of isolation openings and a plurality of light-transmitting openings in an enclosing manner; and
at step S02, preparing on the substrate a light-emitting layer, the light-emitting layer including a plurality of light-emitting units, the light-emitting unit being located at least partially within the isolation opening, and at least one orthographic projection of at least part of the light-transmitting openings on the substrate being positioned between orthographic projections of adjacent light-emitting units of the same color on the substrate.

According to the preparation method of the embodiment of the present application, an isolation structure 200 is prepared on the substrate 100 by step S01, the isolation structure 200 defining light-transmitting openings 250 in an enclosing manner to increase the transmittance of the display panel 10. A light-emitting layer 300 is prepared on the substrate 100 by step S02. When the light-emitting layer 300 is prepared, the light-emitting layer 300 causes a large drop at an edge of the isolation structure 200, and is difficult to connect, resulting in breakage. The light-emitting layer 300 breaks to form light-emitting units 310 which are disconnected from each other and which are located in the isolation openings 240, which eliminates the need for a precision mask plate, reducing the development and use of the precision mask plate and lowering the preparation cost. At least part of the light-transmitting openings 250 are disposed between adjacent light-emitting units 310 of the same color, and the isolation structure 200 and the light-transmitting openings 250 are arranged in a similar manner between the light-emitting units 310 of the same color, which improves the uniformity of the arrangement of the light-transmitting openings 250 between adjacent light-emitting units 310 of the same color, ameliorates poor display of the display panel 10, such as mura, and enhances the display effect of the display panel 10, thereby improving the use performance of OLED display products.

The embodiments of the present application as described above neither set forth all the details, nor do they limit the present disclosure to only the described specific embodiments. Apparently, many modifications and variations can be made in light of the above description. The embodiments are selected and described in this specification to better explain the principles and practical applications of the present application. The present application is limited only by the claims and all the scopes and equivalents thereof.

1. A display panel, the display panel comprising:
a substrate;
an isolation structure on a side of the substrate, the isolation structure defining a plurality of isolation openings and a plurality of light-transmitting openings in an enclosing manner; and
a light-emitting layer on a side of the substrate, the light-emitting layer comprising a plurality of light-emitting units located at least partially within the isolation openings, and at least one orthographic projection of at least part of the light-transmitting openings on the substrate being positioned between orthographic projections of adjacent light-emitting units of the same color on the substrate.

2. The display panel according to claim 1, wherein the plurality of light-emitting units comprise a plurality of first light-emitting units, and the plurality of light-transmitting openings comprise one or more first light-transmitting openings, an orthographic projection of the first light-transmitting openings on the substrate being positioned between orthographic projections of adjacent first light-emitting units on the substrate.

3. The display panel according to claim 2, wherein the plurality of light-emitting units further comprise a plurality of second light-emitting units, and the plurality of light-transmitting openings comprise one or more second light-transmitting openings, an orthographic projection of the second light-transmitting openings on the substrate being positioned between orthographic projections of adjacent second light-emitting units on the substrate.

4. The display panel according to claim 3, wherein the plurality of light-emitting units further comprise a plurality of third light-emitting units, and the plurality of light-transmitting openings comprise one or more third light-transmitting openings, an orthographic projection of the third light-transmitting openings on the substrate being positioned between orthographic projections of adjacent third light-emitting units on the substrate.

5. The display panel according to claim 1, wherein a difference between distances between at least part of the light-transmitting openings and two adjacent light-emitting units of the same color is less than or equal to 1.5 μm.

6. The display panel according to claim 5, wherein the plurality of light-transmitting openings are uniformly distributed in a first direction, or the plurality of light-transmitting openings are uniformly distributed in a second direction.

7. The display panel according to claim 6, wherein the first direction intersects with the second direction.

8. The display panel according to claim 5, wherein a minimum distance between the light-transmitting opening and the light-emitting unit adjacent to one side of the light-transmitting opening in the first direction is a first distance, and a difference between the first distances corresponding to at least part of the light-transmitting openings is less than or equal to 1.5 μm.

9. The display panel according to claim 8, wherein a minimum distance between the light-transmitting opening and the light-emitting unit adjacent to the other side of the light-transmitting opening in the first direction is a second distance, and a difference between the second distances corresponding to at least part of the light-transmitting openings is less than or equal to 1.5 μm.

10. The display panel according to claim 9, wherein a minimum distance between the light-transmitting opening and the light-emitting unit adjacent to one side of the light-transmitting opening in the second direction is a third distance, and a difference between the third distances corresponding to at least part of the light-transmitting openings is less than or equal to 1.5 μm.

11. The display panel according to claim 10, wherein a minimum distance between the light-transmitting opening and the light-emitting unit adjacent to the other side of the light-transmitting opening in the second direction is a fourth distance, and a difference between the fourth distances corresponding to at least part of the light-transmitting openings is less than or equal to 1.5 μm.

12. The display panel according to claim 1, wherein a minimum distance between the light-transmitting opening and the light-emitting unit located on one side of the light-transmitting opening in the first direction is a first distance, and a minimum distance between the light-transmitting opening and the light-emitting unit located on the other side of the light-transmitting opening in the first direction is a second distance, a difference between the first distance and the second distance being less than or equal to 1.5 μm; and a minimum distance between the light-transmitting opening and the light-emitting unit located on one side of the light-transmitting opening in the second direction is a third distance, and a minimum distance between the light-transmitting opening and the light-emitting unit located on the other side of the light-transmitting opening in the second direction is a fourth distance, a difference between the third distance and the fourth distance being less than or equal to 1.5 μm.

13. The display panel according to claim 1, wherein the plurality of light-transmitting openings are arranged at intervals in a first direction in which a difference between a distance between at least part of two adjacent light-transmitting openings and a distance between another two adjacent light-transmitting openings is less than or equal to 1.5 μm;
the plurality of light-transmitting openings are arranged at intervals in a second direction in which a difference between a distance between at least part of two adjacent light-transmitting openings and a distance between another two adjacent light-transmitting openings is less than or equal to 1.5 μm.

14. The display panel according to claim 1, wherein the isolation structure comprises a first layer and a second layer located on a side of the first layer facing away from the substrate, an orthographic projection of the first layer on the substrate being located within an orthographic projection of the second layer on the substrate.

15. The display panel according to claim 1, wherein the display panel further comprises a pixel defining layer on a side of the substrate, the pixel defining layer defining a plurality of pixel openings in an enclosing manner, and the pixel openings communicating with the isolation openings, and the light-emitting unit comprises a second electrode between the substrate and the pixel defining layer, a portion of the second electrode being exposed by the pixel opening.

16. The display panel according to claim 15, wherein the light-emitting unit further comprises a light-emitting device disposed on the second electrode and a first electrode disposed on the light-emitting device, the first electrode being electrically connected to the isolation structure.

17. A display panel, the display panel comprising:
a substrate;
an isolation structure on a side of the substrate, the isolation structure defining a plurality of isolation openings and a plurality of light-transmitting openings in an enclosing manner; and
a light-emitting layer on a side of the substrate, the light-emitting layer comprising a plurality of light-emitting units located at least partially within the isolation openings, and a difference between distances between at least part of the light-transmitting openings and adjacent light-emitting units of the same color being less than or equal to 1.5 μm.

18. The display panel according to claim 17, wherein the difference between distances between at least part of the light-transmitting openings and two adjacent light-emitting units of the same color is less than or equal to 1.5 μm.

19. The display panel according to claim 17, wherein the plurality of light-transmitting openings are arranged at intervals in a first direction in which a difference between a distance between at least part of two adjacent light-transmitting openings and a distance between another two adjacent light-transmitting openings is less than or equal to 1.5 μm;
the plurality of light-transmitting openings are arranged at intervals in a second direction in which a difference between a distance between at least part of two adjacent light-transmitting openings and a distance between another two adjacent light-transmitting openings is less than or equal to 1.5 μm.

20. A method of manufacturing a display panel, the method comprising:
preparing on a substrate an isolation structure, the isolation structure defining a plurality of isolation openings and a plurality of light-transmitting openings in an enclosing manner; and
preparing on the substrate a light-emitting layer, the light-emitting layer comprising a plurality of light-emitting units located at least partially within the isolation openings, and at least one orthographic projection of at least part of the light-transmitting openings on the substrate being positioned between orthographic projections of adjacent light-emitting units of the same color on the substrate.
